(19) United States
(12) Patent Application Publication
(10) Pub. No.: US 2021/0388493 A1
(43) Pub. Date: Dec. 16, 2021

(54) FILM FORMING APPARATUS AND FILM FORMING METHOD

(71) Applicant: TOKYO ELECTRON LIMITED, Tokyo (JP)

(72) Inventors: Yuta SORITA, Yamanashi (JP); Tetsuya SAITO, Yamanashi (JP); Shigeyuki OKURA, Yamanashi (JP); Yuichi FURUYA, Yamanashi (JP); Masamichi HARA, Yamanashi (JP)

(21) Appl. No.: 17/338,128

(22) Filed: Jun. 3, 2021

(30) Foreign Application Priority Data
Jun. 10, 2020 (JP) 2020-101193

(51) Int. Cl. C23C 16/44; C23C 16/46; C23C 16/54; C23C 16/16; C23C 16/455

(52) U.S. Cl. CPC C23C 16/4402; C23C 16/46; C23C 16/45559; C23C 16/16; C23C 16/45565; C23C 16/54

(57) ABSTRACT

A film forming apparatus for forming a film on a substrate includes a chamber, a substrate support, a gas supply unit, a gas injection member, and a filter. The substrate support is disposed in the chamber to support a substrate placed thereon and maintain the substrate at a film forming temperature. The gas supply unit is configured to supply a gas containing a film forming source gas. The gas injection member is disposed to face the substrate support and has a gas injection area for injecting the gas containing the film forming source gas supplied from the gas supply unit. Further, the filter is disposed to cover at least the gas injection area on a surface of the gas injection member opposite to a surface facing the substrate support, the filter being configured to trap particles in the gas containing the film forming source gas while the gas passes therethrough.

### CROSS-REFERENCE TO RELATED APPLICATION

This application claims priority to Japanese Patent Application No. 2020-101193, filed on Jun. 10, 2020, the entire contents of which are incorporated herein by reference.

### TECHNICAL FIELD

The present disclosure relates to a film forming apparatus and a film forming method.

### BACKGROUND

As an example of a technique for forming a film on a substrate, a chemical vapor deposition (CVD) method is known, in which a source gas is supplied onto the substrate to form a film by thermal decomposition or reaction with a reaction gas. In the case of forming a film by the CVD method using a solid-state source at room temperature, a source gas that is generated by vaporizing the solid-state source is supplied to form a film. For example, Japanese Patent Application Publication No. 2015-160963 discloses a technique for forming a ruthenium (Ru) film by vaporizing ruthenium carbonyl (Ru₃(CO)₁₂) that is a solid-state source in a container at room temperature, supplying Ru₃(CO)₁₂ gas into a chamber, and thermally decomposing the Ru₃(CO)₁₂ gas on a substrate.

### SUMMARY

The present disclosure is a film forming apparatus and a film forming method capable of performing film formation in which the influence of particles is suppressed.

In accordance with an aspect of the present disclosure, there is provided a film forming apparatus for forming a film on a substrate, including: a chamber; a substrate support disposed in the chamber and configured to support a substrate placed thereon and maintain the substrate at a film forming temperature; a gas supply unit configured to supply a gas containing a film forming source gas; a gas injection member disposed to face the substrate support, the gas injection member having a gas injection area for injecting the gas containing the film forming source gas supplied from the gas supply unit; and a filter disposed to cover at least the gas injection area on a surface of the gas injection member opposite to a surface facing the substrate support, the filter being configured to trap particles in the gas containing the film forming source gas while the gas passes therethrough.

### BRIEF DESCRIPTION OF THE DRAWINGS

The objects and features of the present disclosure will become apparent from the following description of embodiments, given in conjunction with the accompanying drawings, in which:

FIG. 1 is a cross-sectional view showing a film forming apparatus according to an embodiment;

FIG. 2 is an enlarged cross-sectional view showing a part of a shower head of the film forming apparatus according to the embodiment; and

FIG. 3 is an image showing a structural example of a filter used in the film forming apparatus according to the embodiment.

### DETAILED DESCRIPTION

Hereinafter, embodiments will be described in detail with reference to the accompanying drawings.

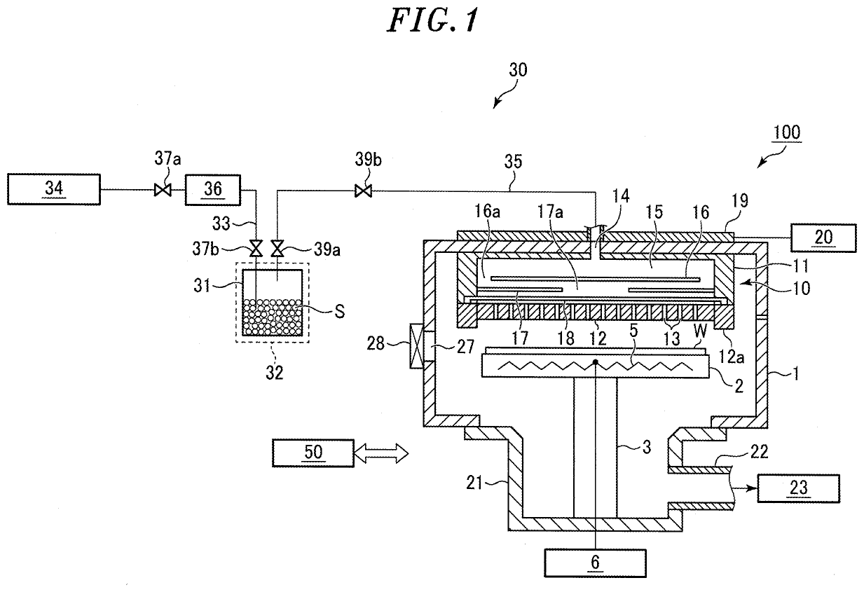

FIG. 1 is a cross-sectional view showing a film forming apparatus according to an embodiment.

A film forming apparatus 100 includes a substantially cylindrical chamber 1 that is airtightly sealed. In the chamber 1, a susceptor 2 serving as a substrate support for horizontally supporting a substrate W such as a semiconductor wafer is disposed. The susceptor 12 is supported by a cylindrical support member 3 disposed at the center of a bottom wall of the chamber 1. A heater 5 is embedded in the susceptor 2. The heater 5 is powered by a heater power supply 6 to generate heat, and the susceptor 2 is heated by the heat thus generated. The substrate W is heated to a desired temperature through the susceptor 2. A heating temperature of the susceptor 2 at this time is controlled by a controller 50 to be described later, based on a detection value of a temperature sensor (not shown) such as a thermocouple or the like. In other words, the susceptor 2 has a function of maintaining the temperature of the substrate W to be a film forming temperature. The susceptor 2 is provided with a plurality of wafer lifter pins (not shown) that protrude beyond and retract below the surface of the susceptor 2 to support and vertically move the wafer W.

A shower head 10 for introducing a processing gas that is used for film formation into the chamber 1 in a shower-like manner is disposed at a ceiling wall (LID) of the chamber 1 to face the susceptor 2. The shower head 10 will be described later in detail.

An exhaust chamber 21 protruding downward is disposed at the bottom wall of the chamber 1. An exhaust pipe 22 is connected to a side surface of the exhaust chamber 21. The exhaust pipe 22 is connected to an exhaust device 23 having a vacuum pump, an automatic pressure control valve, and the like. By operating the exhaust device 23, it is possible to control a pressure in the chamber 1 to a predetermined vacuum level.

A loading/unloading port 27 for loading and unloading the wafer W into and from a vacuum transfer chamber (not shown) is disposed on a sidewall of the chamber 1. The loading/unloading port 27 is opened and closed by a gate valve 28.

The film forming apparatus 100 further includes a gas supply unit 30 for supplying a gas containing a film forming source gas to the shower head 10. The gas supply unit 30 includes a film forming source container 31 that accommodates a film forming source S that is in a solid state at room temperature. As an example of the solid-state film forming source, ruthenium carbonyl (Ru₃(CO)₁₂) may be used. However, the solid-state film forming source at room temperature is not limited to Ru₃(CO)₁₂ and may be another film forming source as long as it has a vapor pressure of 0.1 Pa to 100 Pa at 80° C. Such a film forming source may be, e.g., hexacarbonyl tungsten (W(CO)₆).

The heater 32 is disposed to surround the film forming source container 31. The heater 32 is configured to sublimate the solid-state film forming source S in the film forming source container 31. In the case that the film forming source S is Ru₃(CO)₁₂, Ru₃(CO)₁₂ is heated to about 80° C., for example, in a range from 60° C. to 100° C. where sublimation can occur. A carrier gas supply pipe 33 through which a carrier gas is supplied is inserted into the film forming source container 31 from above. A carrier gas supply source 34 for supplying the carrier gas is connected to the carrier gas supply pipe 33. An inert gas such as Ar gas or N₂ gas can be used as the carrier gas. In the case that the solid-state source is carbonyl such as Ru₃(CO)₁₂, CO gas may be used to suppress decomposition.

Further, a film forming source gas supply pipe 35 is inserted into the film forming source container 31. The film forming source gas supply pipe 35 is connected to the shower head 10. Therefore, when the carrier gas is supplied into the film forming source container 31 through the carrier gas supply pipe 33, the solid-state film forming source S is sublimated in the film forming source container 31 to generate a source gas. Then, the generated source gas is supplied into the chamber 1 through the film forming source gas supply pipe 35 and the shower head 10.

The carrier gas supply pipe 33 is provided with a mass flow controller 36 for flow rate control and valves 37a and 37b disposed at the upstream and downstream of the mass flow controller 36, respectively. Further, the film forming source gas supply pipe 35 is provided with valves 39a and 39b.

The film forming apparatus 100 further includes the controller 50. The controller 50 controls individual components of the film forming apparatus 100 such as the exhaust device 23, the valves and the mass flow controller of the gas supply unit 30, and the like.

Next, the shower head 10 will be described in detail.

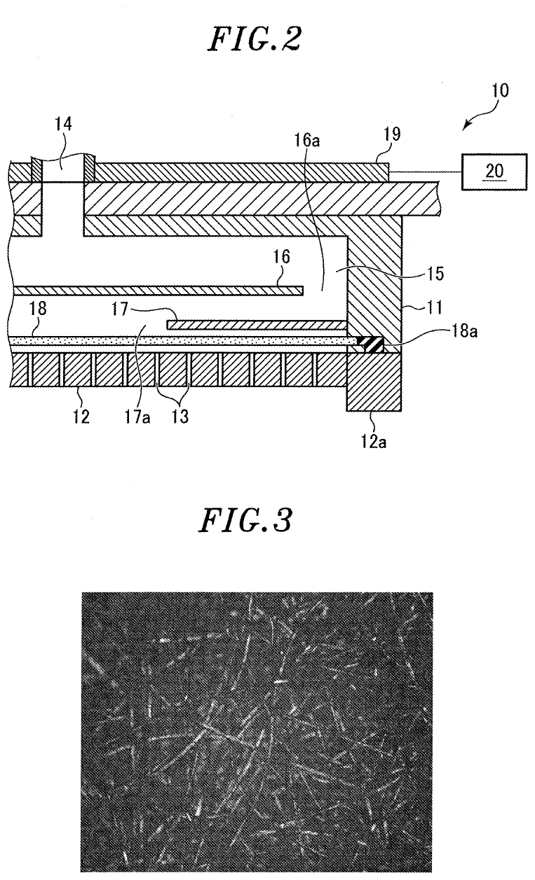

FIG. 2 is an enlarged cross-sectional view showing a part of the shower head 10 of the film forming apparatus 100. As shown in FIG. 2, the shower head 10 includes a cylindrical main body 11 having a ceiling and a lower opening, and a shower plate 12 disposed to block the lower opening of the main body 11. The shower plate 12 has a plurality of gas injection holes 13. The shape of each of the gas injection holes 13 is not limited as long as it has a function of injecting a gas. For example, each gas injection hole 13 may have a circular shape or a slit shape. The shower plate 12 constitutes a gas injection member for injecting a gas containing a film forming source gas from the gas supply unit 30. Further, a gas inlet port 14 is disposed at an upper central portion of the main body 11. A space between the main body 11 and the shower plate 12 serves as a gas diffusion space 15.

In the gas diffusion space 15, a first baffle plate 16 having a ring-shaped through-hole 16a at an outer peripheral portion thereof and a second baffle plate 17 having a circular through-hole 17a at a central portion thereof are horizontally disposed in that order from the top.

A filter 18 is horizontally disposed directly below the second baffle plate 17. The filter 18 has a disc shape and is disposed on a surface of the shower plate 12 opposite to a surface facing the susceptor 2 to cover at least a gas injection area where the gas injection holes 13 are formed. An end portion of the filter 18 is fitted into a sidewall of the main body 11. An outer peripheral frame body 18a is provided at an outer periphery of the filter 18. The outer peripheral frame body 18a is supported by a frame body 12a of the shower plate 12 disposed therebelow. The filter 18 has a function of removing particle components in a gas introduced from the gas inlet port 14.

The filter 18 is, for example, a metal mesh using metal fibers, as shown in the image of FIG. 3. The metal mesh may be obtained by laminating and sintering non-woven fabrics of metal fibers, for example.

Further, the filter 18 used preferably has a conductance that is enough to supply a sufficient amount of the source gas to the substrate W, and has other parameters such as pressure loss, porosity, and the like that are appropriately adjusted to obtain an appropriate conductance.

Further, the filter 18 may have a thickness of, e.g., 0.3 mm to 0.5 mm that is sufficient to appropriately supply the source gas.

Further, the filter 18 is preferably positioned to be closest to the shower plate 12 or may be in contact with the shower plate 12 to reliably trap particles generated in the shower head 10. However, when the filter 18 is in contact with the shower plate 12, a portion of the filter 18 other than a portion in contact with the gas injection holes 13 hardly functions as a filter. Therefore, the filter 18 is preferably separated from the shower plate 12 by a distance of 3 mm to 6 mm so that the entire surface thereof can function as a filter.

An LID heater 19 is disposed on the ceiling wall (LID) of the chamber 1. The LID heater 19 is powered by the heater power supply 20 to heat the shower head 10. A heating temperature at this time is controlled by the controller 50. The heat of the LID heater 19 is transferred to the filter 18 through the outer peripheral frame body 18a and the frame body 12a of the shower plate 12 and heats the filter 18. Accordingly, the particles trapped in the filter 18 can be sublimated. The temperature at this time may be a temperature at which the film forming source can be sublimated. In the case that the film forming source is Ru₃(CO)₁₂, the heating temperature is set to about 80° C. The heater may be dedicated for heating the filter 18.

In the film forming apparatus 100 configured as described above, the gate valve 28 is opened, and the substrate W is loaded into the chamber 1 through the loading/unloading port 27 and placed on the susceptor 2. The susceptor 2 is heated to a desired film forming temperature by the heater 5. An inert gas is introduced into the chamber 1 that is evacuated by the exhaust device 23. Then, the substrate W is heated by the inert gas. Then, a pressure in the chamber 1 is adjusted to a desired pressure by the automatic pressure control valve. The pressure in the chamber at this time is appropriately adjusted depending on the film forming source. For example, the pressure in the chamber is within a range of 0.013 Pa to 133.3 Pa (0.1 mTorr to 1 Torr).

Next, the film forming source container 31 is heated by the heater 32 to a temperature higher than or equal to a sublimation temperature of the film forming source S, and the valves 37a and 37b are opened to supply the carrier gas into the film forming source container 31 through the carrier gas supply pipe 33.

Accordingly, the film forming source gas, for example, Ru₃(CO)₁₂ gas, which is generated by sublimating the solid-state film forming source S by the heat from the heater 32 in the film forming source container 31, is transferred to the film forming source gas supply pipe 35 together with the carrier gas. Then, the film forming source gas is supplied to the shower head 10 through the film forming source gas supply pipe 35 and is injected into the chamber 1 through the gas injection holes 13 of the shower head 10. The source gas injected into the chamber 1 is thermally decomposed on the substrate W placed on the susceptor 2 to form a desired film on the substrate W. In the case of using Ru₃(CO)₁₂ gas as the film forming source gas, Ru₃(CO)₁₂ gas is thermally decomposed on the substrate W to form a Ru film.

The temperature of the susceptor 2 (substrate temperature) at the time of film formation is appropriately set depending on a film forming source to be used or a film to be formed. In the present embodiment, the film forming source gas is thermally decomposed on the substrate to form a film, so that the substrate temperature is set to at least a temperature at which the film forming source can be thermally decomposed. In the case of using Ru₃(CO)₁₂ gas as the film forming source gas, the film forming temperature may be within a range from 100° C. to 300° C.

Although low-temperature film formation may be required depending on the process circumstances, it was found that the number of particles on the substrate W tends to increase in low-temperature film formation. For example, in the case of forming a Ru film using Ru₃(CO)₁₂, the number of particles is small when the temperature of the susceptor 2 is 175° C. However, when the temperature of the susceptor 2 is decreased to 155° C. or lower, the number of particles increases. In particular, as the temperature of the susceptor 2 decreases, the number of fibrous particles considered to be produced by solidifying Ru₃(CO)₁₂ increases.

In other words, it is required to maintain the source gas in a gaseous state until it is heated on the substrate W and thermally decomposed. However, in the case of low-temperature film formation, the source gas is solidified as the temperature thereof decreases until the source gas reaches the substrate W, which may be the main cause of the increase of the particles.

Therefore, in the present embodiment, the filter 18 is disposed in the gas diffusion space 15 of the shower head 10 to cover the gas injection area of the shower plate 12. With such configuration, the gas containing the film forming source gas that has passed through the first and second baffle plates 16 and 17 in the gas diffusion space 15 passes through the filter 18, and the particles are trapped in the filter 18. Accordingly, the adhesion of the particles to the substrate W can be suppressed. The filter 18 is particularly effective in the case of low-temperature film formation in which a large amount of particles are generated due to solidification of the film forming source gas. In the case that the film forming source is Ru₃(CO)₁₂, the filter 18 is effective when the film forming temperature is within a low temperature range of 100° C. to 155° C.

As described above, the filter 18 is preferably separated from the shower plate 12 in the gas diffusion space 15 by a distance of about 3 mm to 6 mm in order to reliably trap the particles generated in the shower head 10 and to effectively realize the function of the filter. In the area of the shower plate 12 on the substrate W side, the heat is sufficiently supplied from the susceptor 2 and there is no risk of re-solidification of the source gas. Therefore, it is not necessary to provide the filter 18 on the side of the shower plate 12 facing the substrate W.

Further, the filter 18 is heated by the LID heater 19 and the trapped particles can be sublimated by heating the filter 18 to a temperature higher than the sublimation temperature of the particles by using the LID heater 19. Thus, it is possible to more reliably prevent the particles from reaching the substrate W. Since the particles do not remain in the filter 18, clogging of the filter 18 does not occur.

Next, a test result demonstrating the effect of the filter 18 will be described. In the present embodiment, the film forming apparatus having the schematic configuration of FIG. 1 was used to form a Ru film on the surface of the semiconductor wafer that is a substrate while using Ru₃(CO)₁₂ as a film forming source. A susceptor temperature was set to 155° C. and a heating temperature of the filter was set to 80° C. For a comparative example, an apparatus that is configured to be the same as the film forming apparatus of FIG. 1 but does not include the filter was used to form a Ru film while using Ru₃(CO)₁₂ as a film forming source and setting the susceptor temperature to 155° C. As the semiconductor wafer, two wafers having a surface made of TaN and two wafers having a surface made of Si were used.

In the comparative example in which no filter is provided, the total number of particles in four semiconductor wafers was 179. Among them, 147 particles were fibrous particles formed by the solidification of Ru₃(CO)₁₂ gas. On the other hand, in the present embodiment in which the filter is provided, the total number of particles in four semiconductor wafers was 44. Among them, 40 particles were fibrous particles.

From the above result, it was confirmed that the total number of particles and the number of fibrous particles formed by solidification of Ru₃(CO)₁₂ gas could be considerably reduced by using the filter. The fibrous particles that are the main particles of the entire particles were reduced by 73% by using the filter.

While various embodiments have been described above, the presently disclosed embodiments are considered in all respects to be illustrative and not restrictive. The above-described embodiments can be embodied in various forms. Further, the above-described embodiments may be omitted, replaced, or changed in various forms without departing from the scope of the appended claims and the gist thereof.

For example, in the above-described embodiments, Ru₃(CO)₁₂ that can form a film by thermal decomposition was used as the film forming source. However, a film may be formed by reaction with a reaction gas.

Further, the film forming apparatus is not limited to that shown in FIG. 1 as long as an apparatus is configured to form a film on the substrate placed on the susceptor by supplying the film forming source gas from the shower head. Further, the shower head may also have a structure in which the film forming source gas passes through the filter.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made departing from the spirit of the disclosures. The accompanying claims and their equivalents are intended to cover such forms or modifications as would fall within the scope and spirit of the disclosures.

1. A film forming apparatus for forming a film on a substrate, comprising:
a chamber;
a substrate support disposed in the chamber and configured to support a substrate placed thereon and maintain the substrate at a film forming temperature;
a gas supply unit configured to supply a gas containing a film forming source gas;
a gas injection member disposed to face the substrate support, the gas injection member having a gas injection area for injecting the gas containing the film forming source gas supplied from the gas supply unit; and
a filter disposed to cover at least the gas injection area on a surface of the gas injection member opposite to a surface facing the substrate support, the filter being configured to trap particles in the gas containing the film forming source gas while the gas passes therethrough.

2. The film forming apparatus of claim 1, wherein the gas injection member is configured as a shower plate constituting a shower head, the shower plate having a plurality of gas injection holes,
the gas injection member is disposed to block a lower opening of a main body of the shower head,
a gas diffusion space is formed between the main body and the gas injection member, and
the filter is disposed in the gas diffusion space.

3. The film forming apparatus of claim 1, wherein the filter is disposed near the gas injection member or is in contact with the gas injection member.

4. The film forming apparatus of claim 2, wherein the filter is disposed near the gas injection member or is in contact with the gas injection member.

5. The film forming apparatus of claim 3, wherein the filter is separated from the gas injection member by a distance of 3 mm to 6 mm.

6. The film forming apparatus of claim 4, wherein the filter is separated from the gas injection member by a distance of 3 mm to 6 mm.

7. The film forming apparatus of claim 1, wherein the filter is a metal mesh using metal fibers.

8. The film forming apparatus of claim 6, wherein the filter is a metal mesh using metal fibers.

9. The film forming apparatus of claim 1, wherein the gas supply unit generates the film forming source gas by sublimating a film forming source that is in a solid-state at a room temperature, and the particles are generated due to re-solidification of the generated film forming source gas.

10. The film forming apparatus of claim 8, wherein the gas supply unit generates the film forming source gas by sublimating a film forming source that is in a solid-state at a room temperature, and the particles are generated due to re-solidification of the generated film forming source gas.

11. The film forming apparatus of claim 9, wherein the film forming source is Ru₃(CO)₁₂.

12. The film forming apparatus of claim 10, wherein the film forming source is Ru₃(CO)₁₂.

13. The film forming apparatus of claim 11, wherein the substrate support is maintained at a temperature ranging from 100° C. to 155° C.

14. The film forming apparatus of claim 12, wherein the substrate support is maintained at a temperature ranging from 100° C. to 155° C.

15. The film forming apparatus of claim 10, further comprising:
a heater configured to heat the filter,
wherein the filter is heated by the heater to sublimate the particles generated due to the re-solidification of the generated film forming source gas.

16. The film forming apparatus of claim 14, further comprising:
a heater configured to heat the filter,
wherein the filter is heated by the heater to sublimate the particles generated due to the re-solidification of the generated film forming source gas.

17. A film forming method for forming a film on a substrate, comprising:
preparing the film forming apparatus described in claim 1;
placing the substrate on the substrate support;
supplying the gas containing the film forming source gas from the gas supply unit toward the substrate on the substrate support;
trapping particles in the gas containing the film forming source gas by allowing the gas containing the film forming source gas to pass through the filter before the gas containing the film forming source gas reaches the substrate on the substrate support; and
forming a film on the substrate using the gas containing the film forming source gas that has passed through the filter.

18. A film forming method for forming a film on a substrate, comprising:
preparing the film forming apparatus described in claim 16;
placing the substrate on the substrate support;
supplying the gas containing the film forming source gas from the gas supply unit toward the substrate on the substrate support;
trapping particles in the gas containing the film forming source gas by allowing the gas containing the film forming source gas to pass through the filter before the gas containing the film forming source gas reaches the substrate on the substrate support; and
forming a film on the substrate using the gas containing the film forming source gas that has passed through the filter.
